(19) United States
(12) Patent Application Publication
(10) Pub. No.: US 2009/0115468 A1
(43) Pub. Date: May 7, 2009

(54) Integrated Circuit and Method for Operating an Integrated Circuit

(75) Inventors: Joerg Berthold, Munich (DE); Matthias Eireiner, Munich (DE); Georg Georgakos, Erding (DE); Stephan Henzler, Taufkirchen (DE); Christian Pacha, Munich (DE); Doris Schmitt-Landsiedel, Ottobrunn (DE)

Correspondence Address: BANNER & WITCOFF, LTD.;Attorneys for client 007052, 1100 13th STREET, N.W., SUITE 1200, WASHINGTON, DC, 20005-4051, US

(73) Assignee: INFINEON TECHNOLOGIES AG, Neubiberg (DE)

(21) Appl. No.: 12/090,165

(22) PCT Filed: Sep. 28, 2006
(86) PCT No.: PCT/DE06/01716

§ 371 Date: Apr. 14, 2008

(30) Foreign Application Priority Data
Oct. 14, 2005 (DE) 10 2005 049 232.0

(51) Int. Cl. H03L 7/00

(52) U.S. Cl. 327/141

(57) ABSTRACT

An integrated circuit, comprising a first data retention element configured to retain the data, the first data retention element having a first setup time, and a second data retention element configured to retain the data, the second data retention element having a second setup time, the second data retention element further having a data input. The second data retention element is connected in parallel with the first data retention element, and the second data retention element is configurable via the data input such that the second setup time is longer than the first setup time.

The invention relates to an integrated circuit and to a method for operating an integrated circuit.

For an integrated data processing circuit, reducing the power loss generated during the data processing is one of the fundamental challenges in modern system-on-chip design. To keep all the contributions to power loss, i.e. both dynamic contributions to power loss and contributions to leakage current loss, as low as possible, it is often desirable to operate the integrated data processing circuit at the lowest possible supply voltage at which the desired functionality, for example in respect of the specific timing requirements, is still assured.

The variations in technology parameters are becoming increasingly important in modern process technologies for producing integrated data processing circuits. These often production-dependent fluctuations in the technology parameters for active integrated components and passive integrated components, including parasitic effects, are reflected in variations in design parameters at higher abstraction levels, for example in variations in signal delays or leakage current. The variations in the technology parameters for the production of an integrated data processing circuit usually have global components and local components, i.e. there are discrepancies which relate to the entire chip, i.e. the entire integrated data processing circuit, but also variants among nominally identical properties within the chip.

In addition to the variations in technology parameters, there are also fluctuations in performance variables which, by way of example, are caused by fluctuations in the supply voltage, for example by current-resistance drop (IR drop) or by crosstalk. These effects are deterministic per se, but cannot be treated as such on account of the underlying complexity and/or depiction in relevant design tools. Instead, they are usually considered and modeled as statistical fluctuations.

The number of technology parameters fluctuating to a statistically significant degree has become ever greater in recent technology generations and the breadths of fluctuation have increased. By way of example, fluctuations arise for a field effect transistor in its width (W), length (L), in the thickness of the oxide (tₒₓ), in its threshold voltage (Vₜₕ) or else in its channel mobility (μ). Interconnects to be produced encounter fluctuations in their width (W), thickness (D), their layer resistance (ρ), their coupling capacitances (C) and their inductances (L), for example. Fluctuations in the operating environment also need to be considered, for example fluctuations in the supply voltage (V_{DD}), in the prevailing temperature (T), in the noise present, in the external radiation present, in the mode of operation, in the activity, in the application, etc.

Worst case analyses and corner analyses are interpreted very pessimistically, which means that the design window closes increasingly when a lead, for example for the operating voltage, is provided separately for each of the fluctuating variables. The statistical static timing analysis (SSTA) takes account of the distribution function for the individual varying technology parameters and therefore provides much more realistic results than conservative approaches. The effects of such a statistical static timing analysis are primarily better modeling of the distribution, which results in an improved yield. However, a statistical approach does not become really meaningful and acceptable until it is combined with adaptive circuit concepts.

Adaptive power supplies are tried and tested and are described in [1] and [2], for example. A fundamental feature for adaptive power supply is how the variations are characterized, i.e. how it is identified whether a chip is too fast or too slow.

In line with the practice described in [1] and [2], what is known as an on-chip speed monitor is used for this purpose, said on-chip speed monitor being used to determine whether or not the required switching speed is being achieved in the circuit. To this end, what is known as an overcritical path is reproduced and a check is performed to determine whether a signal can travel through the overcritical path during a system cycle. Alternatively, the frequency of a ring oscillator can be measured. The drawback of this solution can be seen as being, by way of example, that a speed monitor can depict only global variations. Local variations, which are becoming increasingly important, cannot be countered with a speed monitor. For this reason, in the case of the methods described in [1] and [2], despite the use of a speed monitor, a significant safety margin needs to be incorporated as part of the design of the circuits, since critical paths at other points of the chip may be subject to opposing (local) variations. Even when a very large number of distributed speed monitors are used, local fluctuations cannot be detected. Even with a considerable overhead, such methods cannot guarantee that the timing in adjacent critical paths is reliably observed.

[3] and [4] describe a circuit concept which is also called the razor concept, which can be used to depict both global fluctuations and local fluctuations. If a logic circuit is slightly too slow, the synchronous circuit design results in a setup infringement in the flipflop at which the excessively slow path ends. As described in [3], the fundamental idea of the razor concept is to sample the input signal for the flipflop again shortly after the regular clock edge using a parallel latch/flipflop. Since the clock for this flipflop is delayed, that is to say that the signal is not sampled until later, the signal from this flipflop has a higher likelihood of being valid. If the output signals from the regular flipflop are compared with those from the delayed flipflop, it is possible to see whether a timing error has occurred. In this case, the signal processing can be stopped and the erroneous operation repeated. The error rate is used to regulate or adjust a system parameter such as the circuit's operating voltage. One drawback of this concept can be seen, by way of example, as being that an error rate of greater than zero is required, i.e. errors will actually arise which then need to be corrected. Particularly in a realtime application this cannot be tolerated, primarily because it is not possible to guarantee with any certainty how many of these errors actually occur in a time interval. In a realtime application, such as execution of a protocol stack in a mobile radio telephone, the execution time needs to be determinable at all times on account of the firmly defined latencies. When an error is detected in the original razor concept, one or more instructions need to be executed again, for example and the whole execution of the program is delayed. Furthermore, the error correction requires additional power.

In addition, [5] describes methods for ascertaining critical paths in an integrated data processing circuit.

[6] discloses a programmable timer circuit (timing circuit) which is produced on a chip for integrated circuits and which is used to test the clock time of the functional circuits on the chip. The timer circuit has a selectable input with at least two sources, one of these being a toggle circuit. In addition, the timer circuit has a minimally delayed control path which contains a control latch, and also a programmable delay path which is in parallel with the control path and contains a sample latch. The timer circuit also has a comparator which compares the state of the control latch with that of the sample latch and provides a signal which indicates when the delay path is longer than the control path.

[7] discloses a circuit protected against temporary interfering influences and which has a combinational logic circuit with at least one output. The circuit also has a circuit which provides an error monitoring code for said output. In addition, the circuit has a memory element which is provided at said output and which is controlled by means of the circuit providing the control code such that it is transparent when the control code is correct and holds its state when the control code is incorrect.

[8] discloses a clock generator which has a frequency generator clocked by an input clock signal and also a deskewer circuit, coupled to the frequency generator, for providing an output clock signal whose skew is reduced in comparison with the input clock signal.

[9] discloses a frequency monitoring circuit which has a programmable delay circuit with at least one delay cell which can be selectively activated or deactivated.

The invention is based on a problem of providing an alternative way of improving the characterization of an integrated circuit.

The problem is solved by an integrated circuit and by a method for operating an integrated circuit having the features based on the independent patent claims.

An integrated circuit, for example a first integrated data processing circuit, has at least one data retention element for retaining data, the at least one first data retention element having a first setup time. In addition, the integrated circuit has at least one second data retention element for retaining the data, the at least one second data retention element having a second setup time. The at least one second data retention element is connected in parallel with the at least one first data retention element. The at least one second data retention element is set up or is actuated via its data input such that the second setup time is longer than the first setup time.

In a method for operating an integrated circuit, for example an integrated data processing circuit, data are supplied to at least one first data retention element for retaining the data, the at least one first data retention element having a first setup time. In addition, the data are supplied to at least one second data retention element for retaining the data, the at least one second data retention element having a second setup time. The at least one second data retention element is connected in parallel with the at least one first data retention element, and the second data retention element is set up or is actuated via its data input such that the second setup time is longer than the first setup time.

As a good example, one aspect of the invention can be seen, by way of example, in that although, as also in line with [3], a second latch/flipflop, generally a second data retention element, is used which is connected in parallel with the actual regular flipflop, generally the first data retention element, [3] involves the clock being applied to the second data retention element with a delay and one aspect of the invention involves none of the clocks being delayed, for example both data retention elements, that is to say both flipflops, for example, are supplied with the same clock signal. The setup time of the second data retention element, generally the parallel-connected data retention element, for example the flipflop, is delayed artificially by an appropriate measure, for example by degenerating the second data retention element relative to the first data retention element in respect of the setup time, or by appropriately delaying the data signal on the data path before the data signal, generally the data, is supplied to the data input of the at least one second data retention element.

Hence, one aspect of the invention relates to an adaptive circuit concept which makes it possible to identify how existing variations affect the performance of the chip under consideration and hence the implementation under consideration from the multidimensional random process and to use this information to readjust system parameters in order to comply with the performance specification again. This is the case particularly when the invention is applied to a data processing circuit with critical data paths and optimization of operating parameters, also referred to as system parameters. The system parameters used are, by way of example, the operating voltage or alternatively, by way of example, the clock frequency at which the data retention elements and/or the logic circuits, which are usually likewise contained in the integrated data processing circuit, are clocked.

In line with the circuit concept based on one aspect of the invention, both global fluctuations and local fluctuations are covered, regardless of their origin.

An additional advantage of the invention can be seen, by way of example, in that it is not necessary for an error actually to occur in the data processing. This means that the invention is particularly suitable for realtime applications, for example in a mobile radio telephone for executing a protocol stack, for example on the basis of GSM (Global System for Mobile communications), UMTS (Universal Mobile Telecommunications System), CDMA 2000 (Code Division Multiple Access 2000), FOMA (Freedom of Mobile Multimedia Access), etc., generally on the basis of a second or third generation mobile radio communications standard, for example on the basis of a mobile radio communications standard based on 3GPP (3rd Generation Partnership Project) or 3GPP2 (3rd Generation Partnership Project 2).

Exemplary refinements of the invention can be found in the dependent claims. The refinements described below relate both to the integrated circuit and, insofar as is appropriate, to the method for operating the integrated circuit.

The at least one first data retention element and the at least one second data retention element may be coupled to the same clock signal and hence actuated with the same clock signal.

In addition, the at least one first data retention element and the at least one second data retention element may be a data retention element from the following set of data retention elements:
a nonvolatile memory element, or
a flipflop, particularly a state-controlled flipflop or clock-edge-controlled flipflop, for example a D-type flipflop, an RS-type flipflop or a JK-type flip-flop.

In addition, a comparator, connected downstream of the first data retention element and the second data retention element, for comparing the output signal from the at least one first data retention element with the output signal from the at least one second data retention element may be provided, the comparator providing a comparison result about the comparison between the two output signals. Hence, by way of example, the comparator has the first input of the comparator coupled to an output of the at least one first data retention element and has a second input of the comparator coupled to an output of the at least one second data retention element, so that the two output signals can be supplied to the comparator. The comparator compares the two output signals with one another and the output signal from the comparator, which is provided at the output of the comparator, provides the comparison result signal.

As a good example, the output signal from the at least one first data retention element is therefore generally compared with the output signal from the at least one second data retention element, which produces a comparison result signal.

The comparator may be set up as a comparator providing an Exclusive OR logic function (XOR), for example when an even number of inverters is connected upstream of the second data retention element, for example for the purpose of delaying the timing of the data signal before it is supplied to the second data retention element. Alternatively, however, the comparator may be set up, by way of example, as a comparator providing a Not Exclusive OR logic function (NXOR), for example, when an odd number of inverters is connected upstream of the second data retention element, for example for the purpose of delaying the timing of the data signal before it is supplied to the second data retention element. Hence, it is possible for both an even and an odd number of inverters to be connected upstream of the second data retention element.

In addition, the integrated circuit may have a control unit for controlling at least one operating parameter, on the basis of which the integrated circuit is operated.

In line with one refinement of the invention, the control unit is set up to control at least one of the following operating parameters:
an operating voltage at which at least one portion of the integrated circuit is operated,
an operating frequency at which at least one portion of the integrated circuit is operated,
a body voltage which is applied to the body of the integrated circuit, and
the temperature at which at least one portion of the integrated circuit is operated.

The control unit may be coupled to the comparator, and the control unit may be set up to control the at least one operating parameter on the basis of the comparison result signal.

This allows the operating parameters, for example the operating voltage or the operating frequency of the integrated circuit, to be actuated in optimized fashion taking account of global and local fluctuations in the production process for the integrated circuit, so that, by way of example, the design window in which the integrated circuit may by chance be operated can be reduced further. As a good example, better characterization of the integrated circuit takes place without the need for an error to occur in the data path which is routed to the first data retention element.

The integrated circuit may have a plurality of data processing paths, where each data processing path processes input data, respectively supplied thereto, to produce output data, each data processing path having:
at least one data path input for supplying the input data,
at least one data processing logic unit for processing the supplied input data,
at least one first data retention element for retaining the data processed by means of the data processing logic unit, the at least one first data retention element having a first setup time and the at least one first data retention element providing at least one first data path output signal,
at least one second data retention element for retaining the data processed by means of the data processing logic unit, the at least one second data retention element having a second setup time and the at least one second data retention element providing at least one second data path output signal,
the at least one second data retention element being connected in parallel with the at least one first data retention element,
the second data retention element being set up or being actuated via the data input such that the second setup time is longer than the first setup time.

As a good example, the integrated circuit therefore has a plurality, for example a multiplicity, of data paths, where, by way of example, one data processing path from the data processing paths or a few data processing paths from the data processing paths are critical in terms of timing response, these data paths subsequently also being referred to as critical paths. This refinement of the invention therefore provides a simple way of safely refining the timing response of critical paths which are “protected” by means of the data retention elements and optimizing them such that they can be actuated at a respectively minimized operating voltage while the timing response is still assured.

To save power further, one refinement of the invention provides for the integrated circuit to have a disconnection element which is coupled to the second data retention element such that it can disconnect it independently of the first data retention element.

In addition, the disconnection element may be proportioned such that the second setup time is longer than the first setup time. By way of example, this is made possible by virtue of a disconnection element which supplies the operating voltage to the second data retention element, for example a transistor, for example a field effect transistor, being proportioned such that it has an increased share of the operating voltage dropping across it, for example by virtue of the disconnection element having an increased electrical resistance, so that the second data retention element is operated at an operating voltage which is reduced in comparison with the first data retention element, the effect achieved by this being that the second data retention element has a longer setup time than the first data retention element.

In line with another refinement of the invention, provision is made for the data input of the second data retention element to have a delay element connected upstream of it for delaying the data supplied to the data input of the second data retention element in comparison with the data supplied to the first data retention element. The delay element may be designed such that its delay characteristic can be varied. In line with one refinement of the invention, the delay element has at least one inverter, and in line with another refinement of the invention, at least two inverters connected in series.

In line with yet another refinement of the invention, provision may be made for the data input of the second data retention element to be coupled to the output of the first inverter in the first data retention element. As a good example, an element which is already present in the first data retention element anyway, namely the input inverter of the first data retention element, therefore acts as a delay element for the data which are supplied to the data input of the second data retention element. In line with this refinement of the invention, an additional delay element is not even required in the circuit. Another advantage of this refinement of the invention can be seen in that it also covers local fluctuations which may arise in the two retention elements, and thus the second retention element safely sees the data signal after the first retention element. This is because local fluctuations allow the data input inverter of the parallel flipflop to be very much faster than that of the regular flipflop and thus allow the delay degradation to be equalized.

In line with another refinement of the invention, a variable capacitance is additionally provided in the integrated data processing circuit and is connected between the at least two series-connected inverters.

In addition, the delay element may have a transmission gate, generally any switch, connected between the at least two series-connected inverters. As described above, any number of inverters may be connected upstream of the second data retention element, the comparator providing an XOR function for an even number of upstream inverters and the comparator providing a NOT XOR function for an odd number of upstream inverters.

By way of example, the invention can be applied to signal processors, to memory devices (in this case, for example for rapidly reading information stored in a memory cell array) or pipeline structures having a plurality of series-connected data paths, where a processing logic unit, a data retention element provided at the output of the processing logic unit, a processing logic unit connected downstream of the output of the data retention element as appropriate, a data retention element connected to the output of the subsequent processing logic unit, or a plurality of parallel-connected data retention elements, etc., are respectively provided.

As a good example, one aspect of the invention may be seen as being that the data retention elements, for example flipflops in critical data paths, have a further data retention element (for example an additional flipflop) implemented in them in parallel with the actual signal-carrying data retention element (for example flipflop), said further data retention element having an increased, i.e. longer, setup time in comparison with the first data retention element. When the timing begins to become critical, for example while the operating voltage (also called supply voltage) for operating the integrated data processing circuit is being lowered, the parallel-connected data retention element (for example the parallel-connected flipflop) will see or identify a timing infringement first of all. In other words, in this case the parallel-connected data retention element will first of all experience a timing infringement. Only if the operating conditions are impaired further, for example if there is a further drop in the supply voltage, will the regular data retention element (for example the regular flipflop) also fail. In line with one aspect of the invention, it is possible therefore to compare the two data retention element output signals (for example flipflop output signals) in order to identify when the timing begins to become critical and hence to adjust (tune) the operating parameters of the chip under consideration in order to counteract further timing impairment. For the circuit concept described above, it does not matter whether this tuning process takes place once during system configuration or continually in a continuous control loop or in a discontinuous control loop.

In line with yet another refinement of the invention, provision may be made for the parallel path by means of which the data signal is supplied to the second data retention element to branch off upstream of the first inverter in the “regular” signal path, i.e. the data signal path of the first data retention element, so that the data signal delay occurs totally independently of the data signal propagation signal in the data signal path of the first data retention element. In other words this means that the branch node from which the data signal is routed into the parallel path and hence to the second data retention element is arranged upstream of the first inverter in the “regular” signal path, for example upstream of the first inverter in the master stage of the first data retention element.

In comparison with the concepts based on the prior art, the circuit described above involves both global fluctuations and local fluctuations being taken into account. Errors are not required for the operating principle and do not occur, since the boundary is identified, and counter measures can be taken, even before the absolute limit.

Exemplary embodiments of the invention are illustrated in the figures and are explained in more detail below.

In the figures

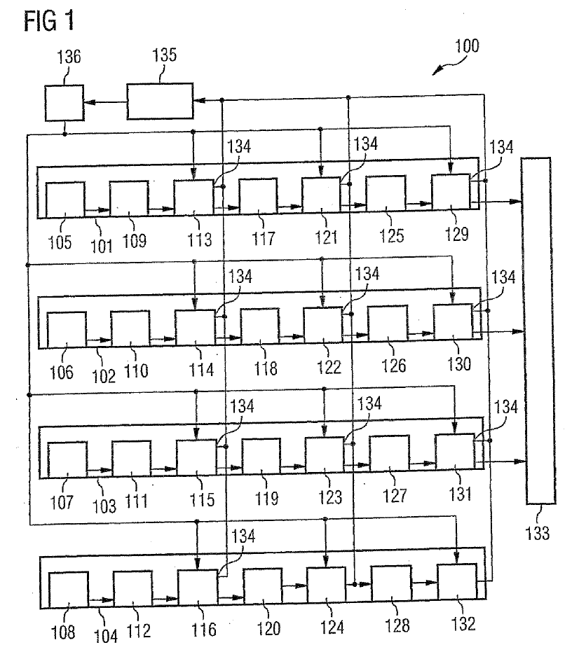

FIG. 1 shows an integrated data processing circuit based on an exemplary embodiment of the invention;

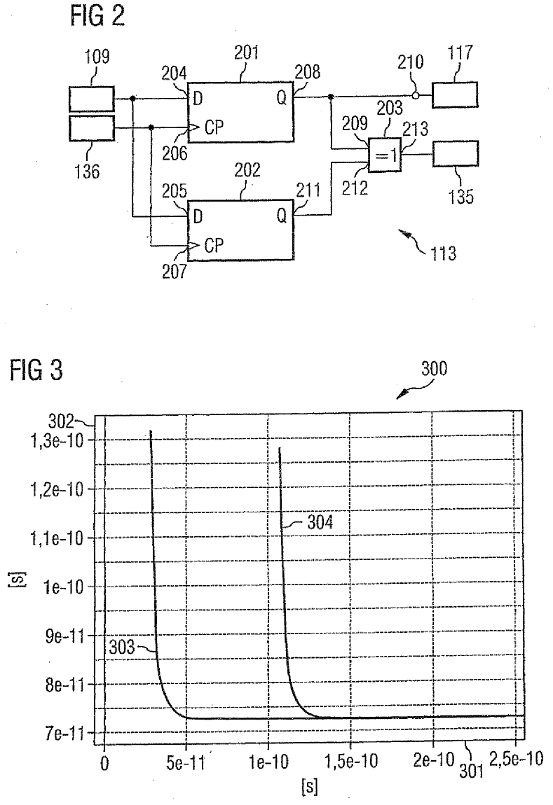

FIG. 2 shows a flipflop circuit based on a first exemplary embodiment of the invention;

FIG. 3 shows a graph showing two different setup characteristics for the flip-flop circuit which is shown in FIG. 2;

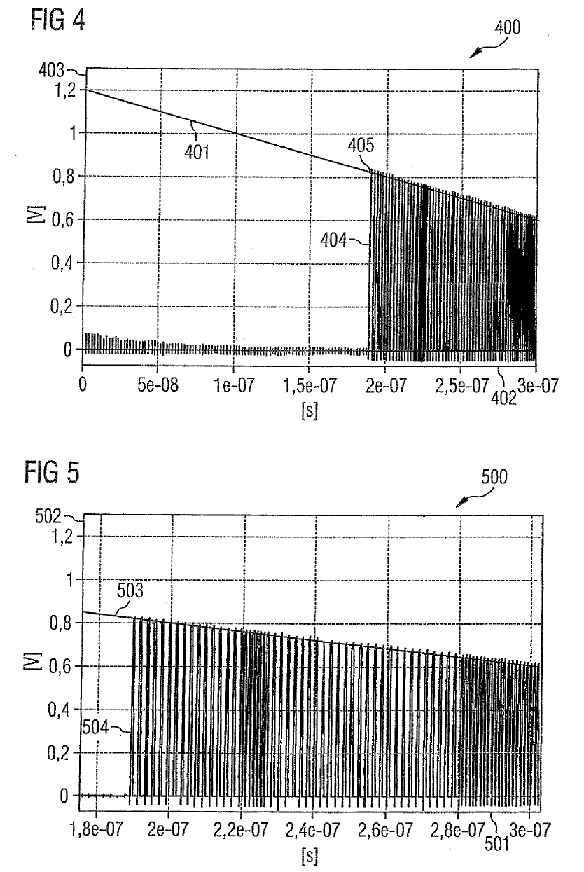

FIG. 4 shows a first graph showing a reduction in the operating voltage for the integrated data processing circuit and the error signal produced in this context;

FIG. 5 shows a second graph showing the lowering of the operating voltage for the integrated data processing circuit and the error signal produced in this context;

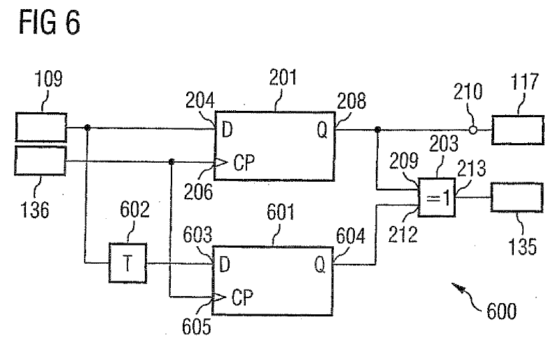

FIG. 6 shows a flipflop circuit based on a second exemplary embodiment of the invention;

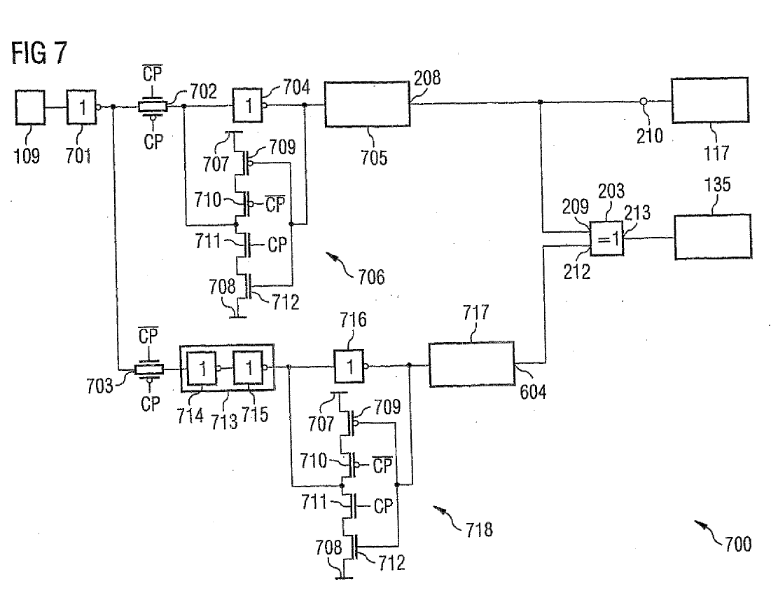

FIG. 7 shows an implementation of the flipflop circuit shown in FIG. 6 at gate level;

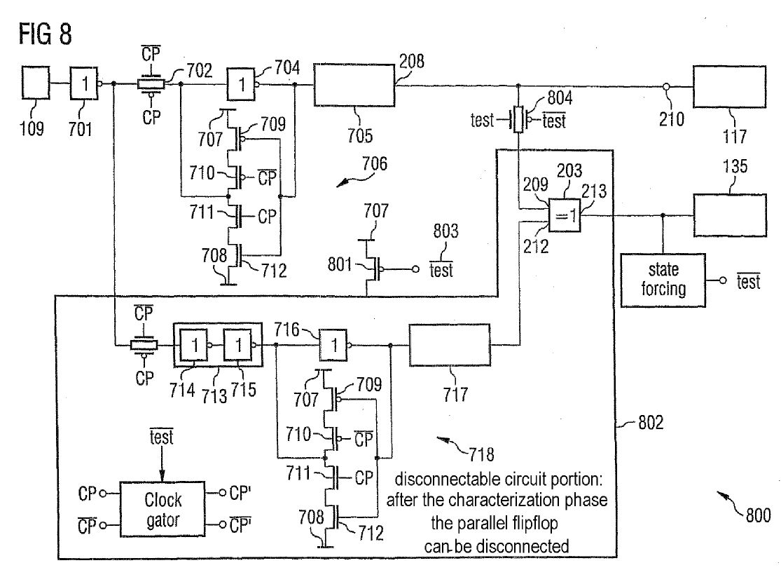

FIG. 8 shows a flipflop circuit based on a third exemplary embodiment of the invention at gate level;

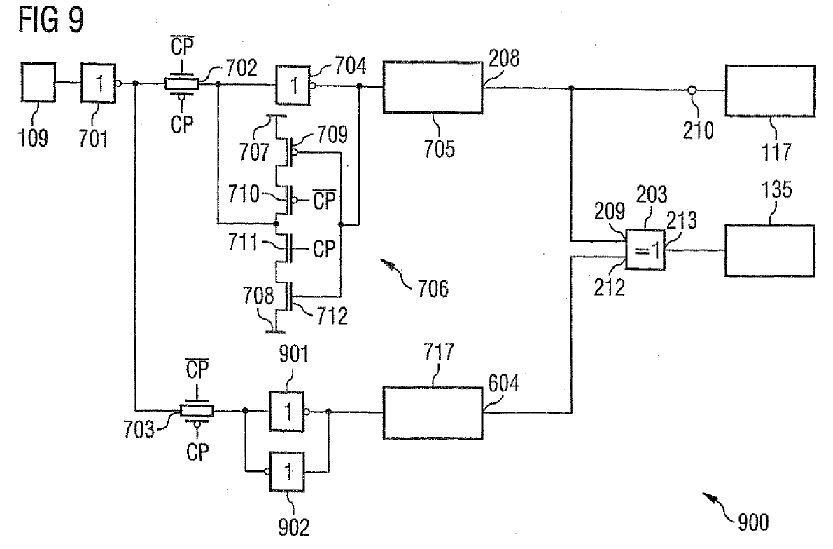

FIG. 9 shows a flipflop circuit based on a fourth exemplary embodiment of the invention at gate level;

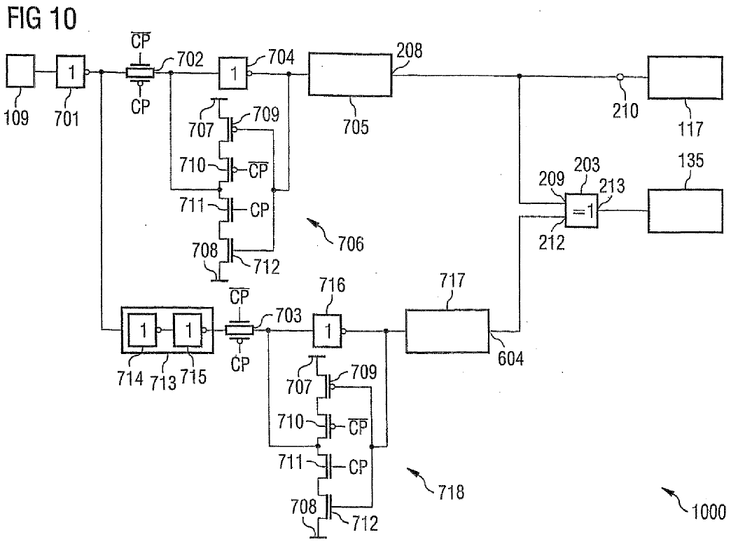

FIG. 10 shows a flipflop circuit based on a fifth exemplary embodiment of the invention at gate level;

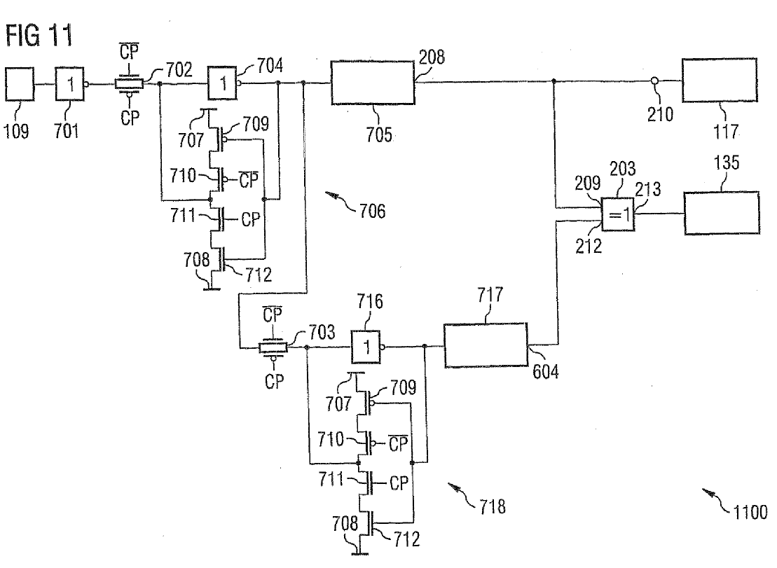

FIG. 11 shows a flipflop circuit based on a sixth exemplary embodiment of the invention at gate level;

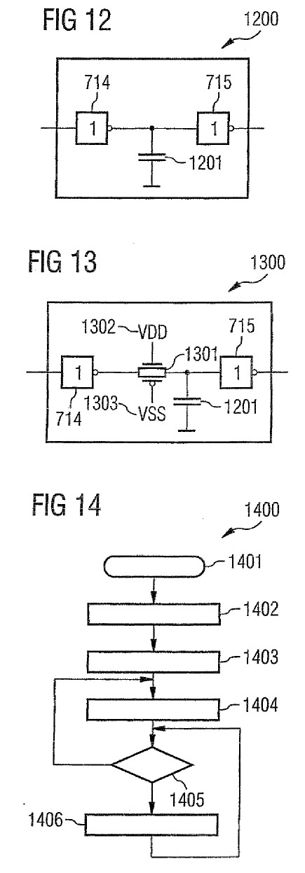

FIG. 12 shows an alternative implementation of the delay element;

FIG. 13 shows another alternative implementation of the delay element;

FIG. 14 shows a flowchart showing a controller algorithm for the regulation of an operating parameter based on an exemplary embodiment of the invention;

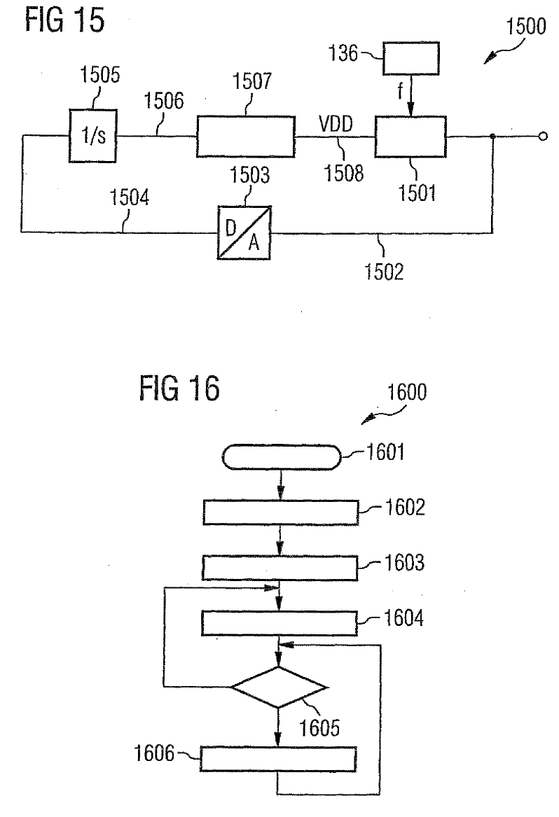

FIG. 15 shows a block diagram of a supply voltage control circuit based on an exemplary embodiment of the invention;

FIG. 16 shows a flowchart showing an alternative algorithm for the selection of an operating parameter based on an exemplary embodiment of the invention;

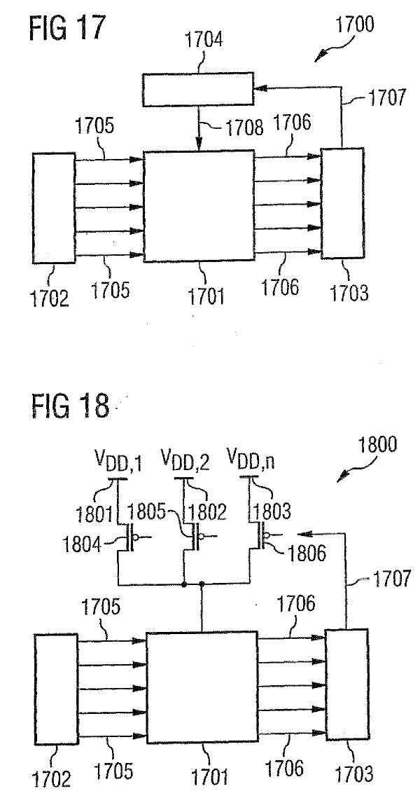

FIG. 17 shows a block diagram of a circuit with continuous-value regulation of the operating voltage;

FIG. 18 shows a block diagram of a circuit with discrete-value regulation of the operating voltage;

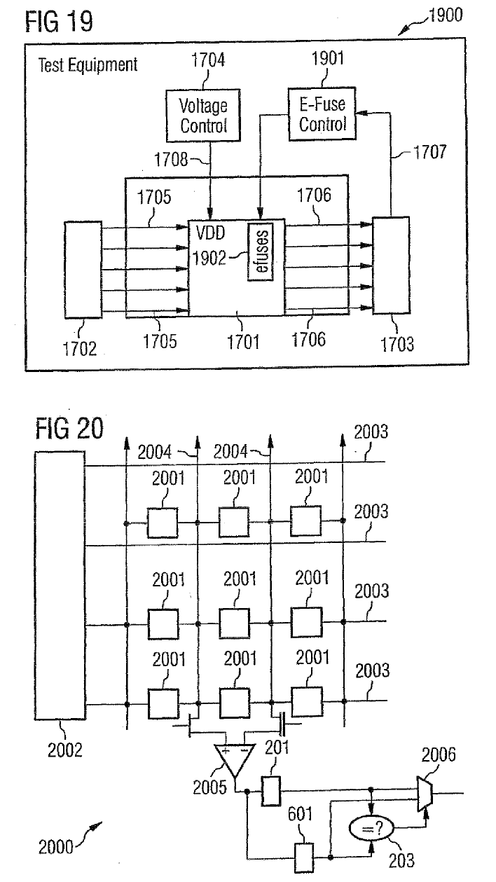

FIG. 19 shows a block diagram of a circuit test arrangement based on a first embodiment of the invention;

FIG. 20 shows a data processing circuit based on another exemplary embodiment of the invention; and

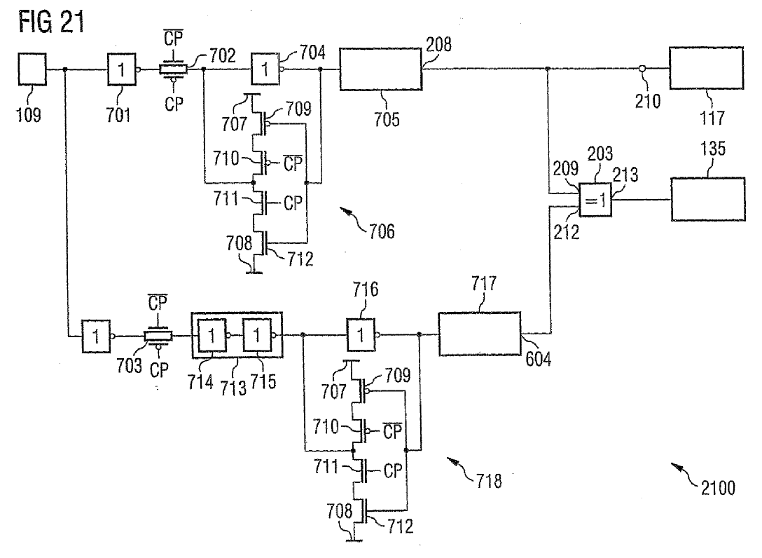

FIG. 21 shows an implementation of the flipflop circuit shown in FIG. 6 at gate level based on another refinement of the invention.

In the figures, the same or identical reference symbols are used for the same or similar elements as far as appropriate.

FIG. 1 shows an integrated data processing circuit 100 based on a first exemplary embodiment of the invention.

The integrated data processing circuit 100 has a multiplicity of data processing paths 101, 102, 103, 104, generally a number n of data processing paths, where n is a natural number greater than or equal to 1.

Each data processing path 101, 102, 103, 104 is supplied with respective data 105, 106, 107, 108 to be processed by the data processing path 101, 102, 103, 104, the data 105, 106, 107, 108 first of all being supplied to a respective first data processing logic unit 109, 110, 111, 112, with the first data processing logic unit 109, 110, 111, 112 respectively implementing possibly even different logic functions using a plurality or multiplicity of logic gates.

The data processed by means of the respective first data processing logic unit 109, 110, 111, 112 are supplied to a respective first flipflop circuit 113, 114, 115, 116 whose design is explained in more detail below.

The data retained by means of the respective first flipflop circuit 113, 114, 115, 116 are supplied at the output to a respective second data processing logic unit 117, 118, 119, 120, the data in the respective second data processing logic unit 117, 118, 119, 120 being implemented in line with a prescribed functionality, implemented in turn by means of an appropriate number of logic gates connected up in a prescribed manner. The second data processing logic units 117, 118, 119, 120 in the different data processing paths 101, 102, 103, 104 may be designed differently, like the first data processing logic units 109, 110, 111, 112 in the different data processing paths 101, 102, 103, 104.

After the logic processing in the respective second data processing logic unit 117, 118, 119, 120, the processed data are supplied to a respective second flipflop circuit 121, 122, 123, 124, which are of the same design as the respective first flipflop circuit 113, 114, 115, 116.

This design of a respective data processing logic unit and a flipflop circuit connected downstream at the output of a respective data processing logic unit is provided in arbitrary repetition in a data processing path, for example an arbitrary number of m data processing logic units and flipflop circuits respectively connected downstream thereof are provided in a data processing path 101, 102, 103, 104, m being an arbitrary natural number greater than 1.

In line with the exemplary embodiment in FIG. 1, the respective second flip-flop circuit 121, 122, 123, 124 is provided with a respective third data processing logic unit 125, 126, 127, 128, which likewise implement prescribed functions provided by means of logic gates. The third data processing logic units 125, 126, 127, 128 in different data processing paths 101, 102, 103, 104 may likewise be designed differently.

At the output, i.e. connected downstream of the respective third data processing logic unit 102, 102, 103, 104, third flipflop circuits 129, 130, 131, 132 are provided.

The output signals provided by means of the third flipflop circuits 129, 130, 131, 132 are processed further in arbitrarily prescribable fashion, for example by means of a microprocessor 133 or by means of a digital signal processor etc.

In addition, each flipflop circuit in the integrated data processing circuit 100 has a respective error signal output 134 at which an error signal is possibly provided. The error signal output is respectively coupled to an input of a control unit 135, which is likewise provided and which picks up the error signals and, on the basis of the error signals, as will be explained in more detail below, regulates operating parameters, for example in this case the clock frequency used or the operating voltage at which the integrated data processing circuit 100 is operated. The output of the control unit 135 is coupled to a clock generator 136 which provides a first clock signal for clocking the flipflop circuits. The output of the clock generator 136 is coupled to a respective clock input of the respective flipflop circuit, as will be explained in more detail below. Alternatively or in addition, a second clock generator may be provided or else the clock generator 136 itself may be provided for the purpose of providing a clock signal for clocking the data processing logic units, provision being able to be made for the data processing logic units to be clocked with the same clock signal or with different clock signals in comparison with the respective flipflop circuit.

It is assumed that the data processing paths 101, 102, 103, 104 are critical in terms of timing response. Hence, the data processing paths 101, 102, 103, 104 in the integrated data processing circuit represent what are known as critical paths which, by way of example, are ascertained using one of the methods described in [5]. It should be pointed out that any, including noncritical, paths may be provided in the data processing circuit 100. In the noncritical paths, the respective flipflop circuit described in detail below is not required, and a simple flipflop circuit with a single regular flipflop may be provided as the flipflop circuit.

If a respective data processing path 101, 102, 103, 104 is to be considered as critical, the flipflop circuit is set up as explained in detail below.

FIG. 2 shows a flipflop circuit 113 for protecting a respective critical path or a data processing logic unit in a respective critical path in detail.

By way of example, the first flipflop circuit 113 is described, although the other flipflop circuits for protecting a critical path or a data processing logic unit in a respective critical path are designed in the same way.

As has been explained above, the first flipflop circuit 113 is connected downstream of the first data processing logic unit 109 and receives the data signal which is produced by the first data processing logic unit 109. The first flipflop circuit 113 has a first state-controlled D-type flipflop 201, and also a state-controlled second D-type flip-flop 202 connected in parallel with the first state-controlled D-type flipflop 201. In addition, a comparator 203 is provided.

The data input 204 of the first D-type flipflop 201 is coupled to the data output of the first data processing logic unit 109, which means that the data signal 105 processed by means of the first data processing logic unit 109 is supplied to the data input 204 of the first D-type flipflop 201. In addition, the data output of the first data processing logic unit 109 has the data input 205 of the second D-type flipflop 202 coupled to it, so that the data signal which is provided by the first data processing logic unit 109 is likewise supplied to the second D-type flipflop 202, and in this context its data input 205.

In addition, the first D-type flipflop 201 has a clock input 206 which is coupled to the clock generator 136 so that the clock signal is supplied to the clock input 206 of the first D-type flipflop. The second D-type flipflop 202 likewise has a clock input 207 which is likewise coupled to the clock generator 136, so that the clock signal supplied to the first D-type flipflop 201 is supplied to the clock input 207 of the second D-type flipflop 202 in the same way. Hence, both D-type flipflops 201, 202 are clocked by means of the same clock signal. In addition, the first D-type flipflop 201 has a data output 208 that is coupled to a first input 209 of the comparator 203 and to a data output 210 of the flipflop circuit 113. The data output 208 of the first D-type flip-flop 201 is used to provide the data output signal from the first D-type flipflop 201.

The second D-type flipflop 202 likewise has a data output 211 at which its data output signal is provided. The data output 211 of the second D-type flipflop 202 is coupled to a second input 212 of the comparator 203. The comparator 203 therefore compares the two data output signals from the two D-type flipflops 201, 202 with one another and produces a comparison result signal, subsequently also called an error signal, which is provided at an output 213 of the comparator 203, the output 213 of the comparator 203, as described above, being the error output of the flipflop circuit 113 and being coupled to the controller circuit 135.

In comparison with the first D-type flipflop 201, the second D-type flipflop 202 has an artificially impaired setup time, in other words an artificially extended setup time. Both D-type flipflops 201, 202 are, as described above, supplied with the same data signals and clock signals. The comparator 203 is used to indicate a comparison between the output signals from the two D-type flipflops 201, 202, which indicates whether or not the data transfer to the two D-type flipflops 201, 202 has worked. If the parallel-connected second D-type flipflop 202 fails, this is an indication for the system level that the timing is becoming critical and the operating voltage must not be lowered further.

In one preferred embodiment, the comparison between the two output signals from the D-type flipflops 201, 202 is performed in sync during the clock phase CP=0. In this way, the influence of what are known as glitches, which can arise on account of the different signal propagation time for the two D-type flipflops 201, 202, is avoided.

If the operating voltage is slowly lowered, the new parallel-connected second D-type flipflop 202 will fail first, while the regular first D-type flipflop 201 still works. The reason for this is that when the timing becomes critical the second D-type flipflop 202 sees or identifies a setup infringement first.

FIG. 3 uses a graph 300 to show setup characteristics for the regular first D-type flipflop 201 and the parallel-connected second D-type flipflop 202 with an extended setup time. The comparator 203 connected downstream of the two D-type flip-flops 201, 202 identifies that the timing threatens to become critical and can report this to the system, for example a test arrangement, for example by setting the error signal to the logic value 1 so that the operating voltage is not lowered further.

In detail, the graph 300 shows the clock-to-output signal (Q) delay axis 302 plotted against the setup time axis 301. In addition, it shows a first characteristic curve 303, which represents the time response of the first D-type flipflop 201, and a second characteristic curve 304, which shows the time response of the second D-type flip-flop 102. It can be seen that the parallel-connected second D-type flipflop 202 is set up or is actuated such that it will fail earlier and as a result will indicate a threatened timing infringement in good time.

The parallel-connected second D-type flipflop 202 therefore supports the adjustment process for speed-related system parameters, for example the operating voltage and/or the clock frequency, by signaling when the genuine critical paths become timing critical. An important distinguishing feature with regard to the prior art in this context is that the critical paths themselves are actually used as an indicator, which means that in contrast to monitor concepts all local effects such as local parameter variations or voltage dips are also taken into account, particularly in the case of full-speed tests. The respective parallel-connected second flipflop can be used for methods which either regulate the voltage of a block under consideration to the ideal value in small quasi-continuous steps or else switch between discrete operating voltage values, as will be explained in more detail below.

In line with one preferred embodiment, this adjustment takes place during the test on the chip or after switching on during a built-in self-test and the configuration mode.

In this connection the term “test” can therefore relate either to an external tester, for example following production of the chip, or to an integrated tester, i.e. a test circuit which is integrated in the chip itself.

In line with one alternative embodiment, the test process and the configuration process are performed afresh at particular periodic or aperiodic intervals.

Continuous regulation strategies are likewise provided in alternative embodiments as will be explained in more detail below.

It should be noted that during the test phase, i.e. the phase in which a speed test is performed and the ideal voltage values stipulated, the critical paths in the data processing circuit 100 are also really sensitized and triggered. This is most easily possible when the critical paths are actively sensitized and initiated for particular test phases and characterization phases, i.e. after switching on or after particular prescribed intervals, for example. The parallel-connected second flipflop 202 can then be disconnected in each case in order to save generated power loss. Alternatively, all the parallel-connected second flipflops 202 or else just a portion thereof can remain connected in order to monitor, in the function of a monitor, whether the operating conditions have worsened, for example on account of a change in temperature. If a flipflop or a plurality of flipflops indicate that timing is becoming critical, this can lead to the configuration mode being initiated again, which tests the individual blocks again and puts them at the optimum voltage value.

The critical paths are ascertained in line with these embodiments of the invention, as described in [5], for example.

In one alternative embodiment, which is likewise described below, provision is made for the regulation to be performed while the system is operating. In this context, it should be ensured that a critical path switches sufficiently often and hence the critical timing is really used for the regulation. This can be achieved by virtue of critical paths being either actively triggered on a regular basis, or else a logic unit ascertaining whether or not a critical path has been sensitized. The output signal from this logic unit can be logically combined with the error signal and used for controlling the controller.

Supplying a circuit block with discrete supply voltage values by switching between various operating voltages can also be applied to smaller circuit blocks, so that the method can be applied in very fine-grained fashion. This allows a better discussion of local variation than in the case of global regulation strategies. In addition, a logic OR function for the individual error signals is easier to implement because it can be implemented locally.

By way of example, the level conversion can be performed in time-efficient and energy-efficient fashion using semi-dynamic level shifter flipflops, since the circuit concept based on the embodiments of the invention means that the voltage allocation is made anyway for entire data processing paths. If the voltage difference is small, for example less than 150 mV, it may be possible to dispense with a level shifter. In this case, a high-threshold gate at the respective voltage interface is advantageous. The assignment to discrete voltage values can be made by means of power switches, which can also be used to isolate the circuit block from the supply voltage in a standby state.

The embodiments of the invention can be used in systems which have different performance modes.

In this case it is advantageous if the delay extension is performed adaptively. The text below explains a few forms of implementation in more detail. In principle, it should be noted that the number of methods known per se, according to the setup time, can be performed discretely (switchable capacitances, different number of stages for delay elements, etc.) or continuously (controllable pass gate resistance, controllable load capacitance, etc.).

The error signals can be logically combined in various ways. One simple option is a logic OR function for the individual signals in order to produce a total error signal. In this case, it is advantageous to combine the Exclusive OR function from the second, parallel-connected flipflop in the flipflop circuit and the individual OR functions in a wired OR gate. Alternatively, it is possible to count the error signals and hence to produce a measure of how critical the timing is for the currently assigned voltage.

In summary, one advantage of the embodiments based on the invention over the prior art can be seen as being that in the case of the embodiments no errors occur or are required for the method to work. There is likewise no extension of the critical path or of the hold time requirement in the case of the embodiments based on the invention.

The overhead in the embodiment based on the invention is tolerable because the parallel-connected second flipflops described need be used only at the end of critical paths.

The second D-type flipflop 202 shown in FIG. 2 has a degenerated setup time in comparison with that of the first D-type flipflop 201, which means that it has a longer setup time in comparison with the first D-type flipflop 201.

FIG. 4 uses a graph 400 to show a linearly falling operating voltage (subsequently also called a supply voltage) 401 plotted in a coordinate system with a time axis 402 and a voltage axis 403. In addition, an error signal 404 for the first D-type flipflop 201 is shown in FIG. 4. From a cutoff voltage 405 onward, errors occur in the first D-type flipflop 201, which means that the voltage cannot be lowered below the cutoff voltage 405.

As a second graph 500 shows in FIG. 5, in which the time 501 is likewise plotted along a first axis and the electrical voltage is plotted along a second axis, the operating voltage 503 is likewise shown in linearly falling fashion, and also an occurrence of the error signal 504 from the second flipflop 202. As FIG. 5 shows, when the operating voltage 503 is lowered or when another performance-related operating parameter is impaired, the parallel-connected second flipflop 202 will fail first and produce an appropriate error signal 504. As illustrated, this generates the error signal 504. If the operating voltage 503 falls further, both flipflops 201, 202 will fail. In this case, no further error signal is generally generated. When the optimum operating voltage is adjusted, preferably during a test or when the circuit is started, the assurance is then usually also given that the voltage has not unintentionally been chosen to be too low and this has been overlooked by the failure of both flipflops 201, 202 and the error signal which is therefore absent. For this purpose, the clock frequency of the system can be lowered slightly, for example briefly. When the clock frequency is lowered, the operation of the original flipflop, i.e. of the first D-type flipflop 201, resumes first while the parallel-connected second D-type flipflop 202 is not yet working. This generates an error signal which indicates that the previously described error has occurred.

Alternatively, to ascertain an error, when desired, an additional flipflop can be connected in parallel and actuated using a delayed clock signal, as described in [3], for example.

FIG. 6 shows a flipflop circuit 600 based on a second exemplary embodiment of the invention, the fundamental design being similar to that of the flipflop circuit 113 shown in FIG. 2.

In contrast to the flipflop circuit 113 shown in FIG. 2, the flipflop circuit 600 based on this alternative embodiment of the invention has a parallel-connected second D-type flipflop 601 which is not degenerate in comparison with the first D-type flipflop 201 and hence, per se has the same timing response characteristics as the first D-type flipflop 201.

In addition, a delay element 602 is connected between the data processing logic unit 109 and the data input 603 of the second D-type flipflop 601 for the purpose of delaying the timing of the supplied data signal. Hence, although the two D-type flipflops 201, 601 are supplied with the same data, said data is applied to the second D-type flipflop 601 with a time delay based on the time delay which is provided or prescribed by the delay element 602. Hence, as a good example, the setup time for the parallel-connected second D-type flipflop 601 is in this case increased by a delay in the supplied data signal.

On account of the different setup times, the two parallel-connected flipflops 210, 601 also have different clock output signal (Q) delays, which means that the comparison between the two output signals which are provided at the data output 208 of the first D-type flipflop 201 and at the data output 604 of the second D-type flipflop 601, may encounter transient maloperation, also referred to as glitches. These can disturb a voltage controller, for example.

For this reason, in line with this embodiment of the invention, the two output signals should not be compared directly after a rising clock edge, but rather a little later, when both output signals are certain to be valid. This can be achieved by additional delay elements or else, in one preferred embodiment, by comparing the output signals during the clock phase CP=0. During this clock phase, both outputs are certainly valid and the comparison is controlled in sync by the clock signal. This makes the comparison insensitive toward variations. It should be pointed out that the clock generator 136 based on this exemplary embodiment of the invention is likewise coupled to the clock input 605 of the second D-type flipflop 601.

The other elements in the flipflop circuit 600 correspond to the elements in the flipflop circuit 113, as is shown in FIG. 2, which is why another description is dispensed with.

FIG. 7 shows an implementation of a flipflop circuit 700 at gate level.

The data processing logic unit 109 has a first inverter 701 provided downstream of it whose output is connected to a first transmission gate 702 and to a second trans-mission gate 703, the two transmission gates 702, 703 being actuated by the clock signal CP or /CP produced by the clock generator 136. The first transmission gate 701 has a second inverter 704 of the master latch connected downstream of it whose output is coupled to the slave latch 705 of the first D-type flipflop 201. In addition, a first transistor circuit 706 is connected in parallel with the second inverter 704, the first transistor circuit 706 having a series circuit, connected between an operating potential 707 and the ground potential 708, comprising four MOS transistors, to be more precise a first PMOS field effect transistor 709 and a second PMOS field effect transistor 710 which is connected in series therewith and which for its part is connected in series with a second NMOS field effect transistor 711 and a first NMOS field effect transistor 712 coupled to ground.

The first PMOS field effect transistor 709 and the first NMOS field effect transistor 712 are coupled to one another by means of their respective gate connections and to the output of the second input inverter 704, and also to the input of the slave latch of the first D-type flipflop 201.

In addition, a first source/drain region of the second PMOS field effect transistor 710 and a first source/drain region of the second NMOS field effect transistor 711 are coupled to one another and also to the input of the second inverter 704 and to the output of the first transmission gate 702.

The gate connection of the second PMOS field effect transistor 710 is connected to the inverted clock signal/CP and the gate connection of the second NMOS field effect transistor 711 is supplied with the clock signal CP itself.

In addition, the second transmission gate 703 has the delay element 713 connected downstream of it which, in line with this embodiment of the invention, has a third inverter 714 and a fourth inverter 715. The delay element 713 has a fifth inverter 716 connected downstream of it which is coupled to the data input of the slave latch 717 of the second D-type flipflop 601.

In addition, a second transistor circuit 718, which is of the same design as the first transistor series circuit 706, is connected in parallel with the fifth inverter 716.

In principle, two modes of operation are provided, where, if the supply voltage for the integrated data processing circuit 100 is intended to be constantly regulated on a continuous basis even during operation thereof (adaptive voltage scaling), the parallel-connected second D-type flipflop 601 is likewise operated on a constantly active basis.

However, if the method is used only for adjusting a suitable operating voltage for the various modes of operation during an initialization phase, the parallel-connected flipflops 202, 601 can also be disconnected in normal operation in order to save power loss.

In one alternative embodiment of the invention, a small portion of the parallel-connected second D-type flipflop 201, 601 can nevertheless remain connected in order to monitor whether the operating conditions may have changed, as a result of which a monitor function is in turn provided.

In one alternative refinement of the invention, provision is made for the delay degradation to be implemented using a second supply voltage supply, which is independent of the supply voltage for the regular data signal path which contains the first D-type flipflop 201.

FIG. 8 shows a flipflop circuit 800 based on another alternative embodiment of the invention as an example of such a separate power supply for the parallel-connected data signal path which contains the second D-type flipflop 202, where the flip-flop circuit 800 corresponds to the flipflop circuit 700 shown in FIG. 7 with the difference that at least one disconnection transistor 801 is provided for disconnecting the circuit components in the data signal path connected in parallel with the regular data signal path, which contains the first D-type flipflop 201, the disconnection transistor 801 being able to activate and deactivate the components in the parallel-connected data signal path selectively on an individual basis. In line with this embodiment, the disconnectable components 802 are the second transmission gate 703, the delay element 713, the fifth inverter 716, the second transistor circuit 718 and the slave latch of the second D-type flipflop 601 and also the comparator 203.

The disconnection transistor 801 as a disconnection element is coupled between the supply potential 707 and the components 802 to be disconnected, the gate connection of the disconnection transistor being actuated by a disconnection signal 803 which indicates whether the mode of operation is a characterization mode of operation for the circuit or the normal mode of operation for the circuit. If it is characterization around the characterization mode of operation, the disconnection transistor 801 in the form of a PMOS field effect transistor is turned on, so that the components in the parallel path are supplied with power; in normal operation the disconnection transistor 801 is deactivated, so that the components 802 are not supplied with power.

In another alternative embodiment, which is not shown, provision is made for the delay element 713 to be replaced by proportioning the disconnection transistor 801 to be so small that the disconnection transistor 801 has so much electrical voltage dropping across it from the operating voltage 706 that the setup time for the second D-type flipflop 601 is extended to a sufficient degree to achieve the desired functionality. This is achieved by increasing the appropriate electrical resistance which is formed by the disconnection transistor 801, for example.

In general, different disconnection methods may be provided for disconnecting the parallel-connected second D-type flipflop 201, 601 or the additional components in the parallel data path, for example isolation of the input and the output of the parallel-connected second D-type flipflop 201, 601 by means of C²MOS inverters, tristate buffers, transmission gates, etc., or alternatively clock gating and power gating. Combinations of these techniques are also provided in alternative embodiments of the invention.

In addition, a third transmission gate 804 is connected between the output of the first D-type flipflop 201 and the first input 209 of the comparator 203, the third transmission gate 804 being switched by means of the disconnection signal 803.

FIG. 9 shows another flipflop circuit 900, which is of similar design to the flip-flop circuit 700 in FIG. 7, the first D-type flipflop 201 having greater contention, which achieves the increase in the setup time in the second D-type flipflop 601.

Thus, the parallel path of the flipflop circuit 900 contains a sixth inverter 901 for the second transmission gate 703 and, fed back in parallel with said inverter 901, a seventh inverter 902. Additional delay elements are dispensed with in this embodiment.

FIG. 10 shows another alternative refinement of a flipflop circuit 1000, in which the delay element 708 is connected upstream of the second transmission gate 703. Hence, the flipflop circuit 1000 shown in FIG. 10 is of the same design as the flipflop circuit 700 shown in FIG. 7.

FIG. 11 shows another alternative refinement of a flipflop circuit 1100, in which the delay element has been omitted.

In this exemplary embodiment the output of the second inverter 704 is coupled additionally to the input of the second transmission gate 703, as a result of which the desired delay in the data signal and hence the desired setup time extension in the second D-type flipflop 201, 601 are achieved. Otherwise, the flipflop circuit 1100 shown in FIG. 11 is of the same design as the flipflop circuit 700 shown in FIG. 7.

In an exemplary embodiment which is not shown, the flipflop circuit 1100 shown in FIG. 11 can be extended by providing the delay element, in which case the output of the second inverter 704 is additionally coupled to the input of the delay element.

FIG. 12 shows an alternative refinement of the delay element 1200, where the two series-connected inverters 714, 715 have a variable capacitance (tunable capacitance) 1201 connected between them. The use of the tunable capacitance 1201 allows the setup time of the parallel-connected second D-type flipflop 601 to be made adjustable. In this way, the method is likewise matched to various modes of operation.

FIG. 13 shows yet another alternative refinement of the delay element 1300, where the second inverter 714 and the third inverter 715 have a fourth transmission gate 1301 connected between them whose first control input is coupled to the operating potential V_{DD} 1302 and whose second control input is connected to a second operating potential V_{SS} 1203. By tuning the tunable capacitance 1201 or the control signal for the fourth transmission gate 1301, it is possible to adapt the setup time for the second D-type flipflop 601.

FIG. 14 uses a flowchart 1400 to show a method for regulating an operating parameter for the integrated data processing circuit 100, in line with this embodiment for regulating the supply voltage to a minimum admissible value at which, despite the relatively low supply voltage, there are still no errors occurring within the integrated data processing circuit 100. This method is carried out during the test or the initialization process, for example.

When the system has started (step 1400), the operating voltage is set to the usually maximum value (step 1402) and the test mode is started (step 1403). In a subsequent step, the value of the operating voltage (V_{DD}) is reduced (step 1404) and a check is performed to determine whether on the basis of the flipflop circuits described above, an error is predicted in the respective processing path 101, 102, 103, 104 (step 1405). If this is not the case, the method is continued in step 1404 and the operating voltage V_{DD} is reduced further. If the checking step 1405 establishes that an error is forecast, however, it being worth noting that an error has not yet occurred in this case, then the value of the operating voltage V_{DD} is again increased a little (step 1406) and the method continued in checking step 1305, i.e. the value of the operating voltage V_{DD} is increased further until it is again established in checking step 1405 that no error will occur in the integrated data processing circuit 100.

FIG. 15 uses a block diagram 1500 to show the individual elements for regulating the operating voltage, in other words the supply voltage. For every flipflop circuit or its upstream data processing logic unit 1501, which is operated at a prescribed clock frequency f prescribed by the clock generator 136, it is ascertained whether an error signal 1502 is produced. If this is the case then the error signal 1502 produced is subjected to digital/analog conversion in a digital/analog converter 1503 and the analog-converted error signal 1504 is supplied to a 1/s controller 1505, i.e. a differential controller, which produces an analog controlled variable 1506 and supplies it to a voltage converter 1507, which takes the controller signal 1506 as a basis for providing the operating voltage V_{DD} 1508 for the respective data processing logic unit 1501.

By way of example, the regulation can take place permanently, i.e. continuously (adaptive supply scaling), or, in one alternative embodiment, only during particular prescribable initialization processes or configuration processes.

FIG. 16 uses another flowchart 1600 to show an alternative option for adjusting the supply voltage V_{DD}, generally an arbitrary operating parameter for operating the integrated data processing circuit.

In line with this method, when a system has been started up (step 1601), the value of the supply voltage V_{DD} is set to a usual maximum value (step 1602) and the test mode of operation is started (step 1603).

In a subsequent step, there is a switch to a discontinuous prescribed lower supply voltage value (step 1604) and a check is performed to determine whether, on the basis of the details from the respective flipflop circuit, an error is to be expected or an error is predicted (checking step 1605).

If this is not the case, the method is continued in step 1604, in which there is a switch to an, in turn, lower operating supply voltage value level (step 1604).

If the checking step 1605 ascertains that an error is predicted, however, then a subsequent step (step 1606) switches to the next highest discontinuous supply voltage value and the method is continued in checking step 1605.

Hence, this method takes a discrete set of available options, i.e. takes a discrete set of prescribable supply voltage values to be used, and selects a supply voltage value and respectively checks whether or not an error is to be expected, and if this is not the case then the next lowest supply voltage value is selected. If an error is forecast, the respective next highest supply voltage value is selected and is supplied to the respective data processing circuit.

FIG. 17 uses a block diagram 1700 to show a tester arrangement with the integrated circuit 1701 to be tested, which is designed in line with the integrated circuit 100 shown in FIG. 1, for example, a test pattern generator 1702, an evaluation unit 1703 and a voltage controller 1704.

The test pattern generator 1700 produces test patterns for testing the integrated circuit 1701 and supplies the test patterns 1705 to the integrated circuit 1701. Test result signals 1706 are produced by the integrated circuit 1701 and are supplied to the evaluation unit 1703 and evaluated there. On the basis of the test evaluation and a test evaluation signal 1707 produced as part of this by the evaluation unit 1703, said signal being supplied to the voltage controller 1704, the voltage controller 1704 is used to regulate the voltage 1708 supplied to the integrated circuit 1701. This is done during a configuration phase, for example. The test patterns 1705 are usually critical test patterns for the timing of the integrated circuit 1701.

FIG. 18 shows an alternative tester arrangement 1800 which differs from the test arrangement 1700 particularly in that a plurality of, in line with this exemplary embodiment of the invention, three different supply voltage sources 1801, 1802, 1803 are provided, the first supply voltage source 1801 providing a first supply voltage V_{DD,1}, the second supply voltage source 1802 providing a second supply voltage V_{DD,2} and the third supply voltage source 1803 providing a third supply voltage V_{DD,n}.

In general, any number of supply voltage sources and different supply voltages provided by them are provided. This allows different operating voltage values to be allocated discretely. The respective supply voltage sources 1801, 1802, 1803 are selected by means of appropriate engagement elements, in line with this exemplary embodiment in the form of power switches 1804, 1805, 1806, under the control of appropriate control signals and are supplied to the integrated circuit 1701.

During a configuration phase, this embodiment of the invention also involves time-critical test patterns 1705 being applied to the respective block or to the integrated circuit 1701, the error signals 1706 from the flipflop circuits are evaluated and the ideal, optimized supply voltage is selected from the multiplicity of prescribed values for discrete supply voltages. In addition, the power switches 1804, 1805, 1806 can be used in standby mode in order to isolate the circuit block i.e. the integrated circuit 1701, from the supply voltage, and thereby to reduce the leakage current in the overall circuit.

To avoid an area increase for n power switches 1804, 1805, 1806 (approximately n*5% of the chip area is required), the supply voltage V_{DD} can be lowered to the relevant minimum possible voltage value during the test and stored on the chip, for example, i.e. on the integrated circuit 1701, for example, by appropriately programming electrical fuses (electronic fuses) or laser fuses.

FIG. 19 shows another alternative tester arrangement 1900 with an electronic fuse control unit 1901 which blows electrical fuses 1902 in the electronic circuit 1701 in response to the control signals from the evaluation unit 1703.

The application of suitable input signals is used to sensitize the critical paths, for example using the signals 1705 produced by the test pattern generator 1702, and then to check the levels of the relevant Exclusive OR gates. In this case, the voltage 1708 is gradually reduced from a maximum value to the value at which an error occurs or an error is forecast. By way of example, the voltage value 1708 established in this way is set down in the circuit block 1701 using configuration fuses 1902. Upon later use, the circuit block 1701 supplies this value to the voltage generator 1704, which is usually situated on a separate chip (also called power chip). This process can be performed for all modes of operation in order to establish the respective minimum voltage required.

Improved characterization of the actual chip characteristics, in other words of the characteristics of the integrated circuit, which is achieved in line with these embodiments of the invention, the lead for the operating voltage or the supply voltage can be reduced. This means that really only the voltage which is required for assuring the functionality of the integrated circuit is used. The plurality of all the chips therefore requires significantly less power, which means that more stringent power specifications can also be observed. Very slow chips can be supplied with an increased supply voltage by the method and thereby speeded up such that they can still be presented and sold as functionally admissible.

Without this adaptive method, this would not be possible since an increased voltage would move very fast instances of integrated circuits from the power specification anyway.

In the case of chips or integrated circuits which are too slow, this does not normally happen as a result of a voltage increase, since they are not only slow but also low in leakage current.

FIG. 20 shows a memory circuit 2000, which has an array of memory cells 2001. In this example, only three rows of memory cells 2001 are shown without restricting general validity, but any number of rows and columns may be provided in the memory cell array.

In normal operation of the memory cell arrangement 2000, a decoder 2002 receives a memory address which is used to indicate the address of a memory cell 2001 which is to be accessed, and this memory address is decoded such that one of the word lines 2003 is activated. The word lines 2003 are used to couple the memory cells 2001 on that line to the respective bit line pairs 2004.

Depending on whether or not a bit is stored in the respective memory cell 2001, an alteration is caused in the electrical flow of current in the bit lines of the respective bit line pair 2004, the current flowing through the bit lines being detected by a current detection amplifier 2005 (sense amplifier) connected to the bit lines. The output of the current detection amplifier 2005 is stored in the first D-type flipflop 201 and in the parallel-stored second D-type flipflop 601.

The comparator 203 provided, which is connected downstream of the flipflop circuit connected downstream of the sense amplifier 1906, is used to compare whether the signal detected by the sense amplifier 2005 has been detected correctly.

If this is the case, a multiplexer 2006 connected to the output of the comparator 203 is used to output the detected memory cell current signal read which is stored in the first D-type flipflop 201.

FIG. 21 shows another implementation of a flipflop circuit 2100 at gate level. The flipflop circuit 2100 is based on the flipflop circuit 700 shown in FIG. 7 with the difference that the parallel path by means of which the data signal is supplied to the second data retention element branches off upstream of the first inverter 701 in the “regular” signal path, i.e. the data signal path for the first data retention element, which means that the data signal delay is effected completely independently of the data signal propagation in the data signal path of the first data retention element. In other words, this means that the branch node from which the data signal is routed into the parallel path and hence to the second data retention element is arranged upstream of the first inverter 701 in the “regular” signal path, for example upstream of the first inverter in the master stage of the first data retention element.

In alternative refinements of the invention, the branching off of the parallel path by means of which the data signal is supplied to the second data retention element upstream of the first inverter 701 can also be applied to the circuits shown in FIG. 8, FIG. 9, FIG. 10 and FIG. 11.

The invention can be used in any data processing circuits, for example with any pipeline structure.

In particular, the invention is suitable for use by realtime areas of application, for example in the field of signal processors.

It should be noted that the implementations described above can be combined with one another in arbitrary fashion, as far as appropriate.

This document has cited the following publications:
[1] Tschanz et al., Effectiveness of Adaptive Supply Voltage and Body Bias for Reducing Impact of Parameter Variations in Low-Power and High-Performance Microprocessors, Journal of Solid State Circuits, Vol. 38, No. 5, 2003;
[2] Tschanz et al., Adaptive Body Bias for Reducing Impact of Die-to-Die Parameter Variations on Microprocessor Frequency and Leakage, International Solid State Circuits Conference, 2002;
[3] WO 2004/084070 A1
[4] D. Ernst et al., Razor: A Low-Power Pipeline Based on Circuit-Level Timing Speculation, Proceedings of the 36th International Symposium on Microarchitecture, 2003;
[5] H. Yalcin et al., Hierarchical Timing Analysis Using Conditional Delays, Digest of Technical Papers of International Conference on Computer-Aided Design, 1995;
[6] US 2001/0013111 A1
[7] WO 00/54410 A1
[8] U.S. Pat. No. 6,507,230 B1
[9] U.S. Pat. No. 6,272,439 B1.

### LIST OF REFERENCE SYMBOLS

100 Data processing circuit
101 Data processing path
102 Data processing path
103 Data processing path
104 Data processing path
105 First data
106 Second data
107 Third data
108 Fourth data
109 First data processing logic unit
110 First data processing logic unit
111 First data processing logic unit
112 First data processing logic unit
113 First flipflop circuit
114 First flipflop circuit
115 First flipflop circuit
116 First flipflop circuit
117 Second data processing logic unit
118 Second data processing logic unit
119 Second data processing logic unit
120 Second data processing logic unit
121 Second flipflop circuit
122 Second flipflop circuit
123 Second flipflop circuit
124 Second flipflop circuit
125 Third data processing logic unit
126 Third data processing logic unit
127 Third data processing logic unit
128 Third data processing logic unit
129 Third flipflop circuit
130 Third flipflop circuit
131 Third flipflop circuit
132 Third flipflop circuit
133 Microprocessor
134 Error signal output
135 Controller unit
136 Clock generator
201 First D-type flip-flop
202 Second D-type flip-flop
203 Comparator
204 Data input of the first D-type flip-flop
205 Data input of the second D-type flip-flop
206 Clock input of the first D-type flip-flop
207 Clock input of the second D-type flip-flop
208 Data output of the first D-type flip-flop
209 First input comparator
210 Data output of flipflop circuit
211 Data output of the second D-type flip-flop
212 Second input comparator
213 Error signal output of flipflop circuit
300 Graph
301 Time axis
302 Clock-to-output signal delay
303 Characteristic curve of first D-type flip-flop
304 Characteristic curve of second D-type flip-flop
400 Graph
401 Supply voltage profile
402 Time axis
403 Voltage axis
404 Error signal
405 Cutoff voltage
500 Graph
501 Time axis
502 Voltage axis
503 Supply voltage
504 Error signal
600 Flipflop circuit
601 Second D-type flip-flop
602 Delay element
603 Data input of the second D-type flip-flop
604 Data output of the second D-type flip-flop
605 Clock input of the second D-type flip-flop
700 Flipflop circuit
701 First inverter
702 First transmission gate
703 Second transmission gate
704 Second inverter
705 Slave latch of the first D-type flip-flop
706 First transistor circuit
707 Supply potential
708 Ground potential
709 First PMOS field effect transistor
710 Second PMOS field effect transistor
711 Second NMOS field effect transistor
712 First NMOS field effect transistor
713 Delay element
714 Third inverter
715 Fourth inverter
716 Fifth inverter
717 Slave latch of the second D-type flip-flop
718 Second transistor circuit
800 Flipflop circuit
801 Disconnection transistor
802 Component parallel path
803 Disconnection signal
804 Third transmission gate
900 Flipflop circuit
901 Sixth inverter
902 Seventh inverter
1000 Flipflop circuit
1100 Flipflop circuit
1200 Delay element
1201 Tunable capacitance
1300 Delay element
1301 Fourth transmission gate
1302 First reference-ground potential
1303 Second reference-ground potential
1400 Flowchart
1401 Start system
1402 Set supply voltage to maximum value
1403 Start test mode
1404 Reduce supply voltage
1405 Is error predicted?
1406 Increase supply voltage
1500 Controller circuit
1501 Integrated circuit
1502 Error signal
1503 Digital/analog converter
1504 Analog-converted error signal
1505 Controller unit
1506 Control signal
1507 Voltage converter
1508 Supply voltage
1600 Flowchart
1601 Start the system
1602 Set supply voltage to maximum value
1603 Start test mode
1604 Switch to lower supply voltage
1605 Is error predicted?
1606 Switch to higher supply voltage
1700 Tester arrangement
1701 Integrated circuit
1702 Test pattern generator
1703 Evaluation unit
1704 Voltage controller
1705 Test pattern signal
1706 Test result signal
1707 Evaluation result signal
1708 Supply voltage
1800 Tester arrangement
1801 First supply voltage source
1802 Second supply voltage source
1803 Third supply voltage source
1804 First power switch
1805 Second power switch
1806 Third power switch
1900 Tester arrangement
1901 Electronic fuse control unit
1902 Electronic fuses
2000 Memory cell arrangement
2001 Memory cell
2002 Decoder
2003 Word line
2004 Bit line
2005 Current detection amplifier
2006 Multiplexer
2100 Flipflop circuit

1. An integrated circuit, comprising:
first data retention element the data, the first data retention element having a first setup time,
second data retention element configured to retain the data, the second data retention element having a second setup time, the second data retention element further having a data input,
wherein the second data retention element is connected in parallel with the first data retention element, and
wherein the second data retention element is configurable via the data input such that the second setup time is longer than the first setup time.

2. The integrated circuit as claimed in claim 1,
wherein the integrated circuit is configured as an integrated data processing circuit.

3. The integrated circuit as claimed in claim 1,
wherein the first data retention element and the second data retention element are coupled to a same clock signal.

4. The integrated circuit as claimed in claim 1,
wherein the first data retention element and the second data retention element and the second data retention element are each a data retention element selected from the following set of data retention elements:
a nonvolatile memory element,
a state-controlled flipflop, and
a clock-edge-controlled flip-flop.

5. The integrated circuit as claimed in claim 1, further comprising:
a comparator, connected downstream of the first data retention element and the second data retention element, the configured to compare an output signal from the first data retention element with an output signal from the second data retention element, and to provide a comparison result signal based on the comparison.

6. The integrated circuit as claimed in claim 5, further comprising:
a control unit configured to control an operating parameter, on the basis of which the integrated data processing circuit is operated.

7. The integrated circuit as claimed in claim 6,
wherein the operating parameter is one of the following operating parameters:
an operating voltage at which at least a portion of the integrated data processing circuit is operated,
an operating frequency at which at least a portion of the integrated data processing circuit is operated,
a body voltage applied to a body of the integrated data processing circuit,
a temperature at which at least a portion of the integrated data processing circuit is operated.

8. The integrated circuit as claimed in claim 6, wherein the control unit is coupled to the comparator.

9. The integrated circuit as claimed in claim 8,
wherein the control unit is configured to control the operating parameter on the basis of the comparison result signal.

10. An integrated circuit, comprising:
a plurality of data processing paths, wherein each data processing path is configured to process input data respectively supplied thereto, to produce output data, each data processing path having:
a data path input for supplying the input data,
a data processing logic unit configured to process the supplied input data,
first data retention element, which is further configured to retain the data processed by the data processing logic unit, th first data retention element having a first setup time and the at least one first data retention element providing a first data path output signal,
second data retention element, which is further configure to retain the data processed by the data processing logic unit, the second data retention element having a second setup time and the at least one second data retention element providing a second data path output signal,
the second data retention element being connected in parallel with the first data retention element,
the second data retention element being configurable via the data input such that the second setup time is longer than the first setup time.

11. The integrated circuit as claimed in claim 10, further comprising:
a disconnection element which is coupled to the second data retention element and configured to disconnect the second data retention element independently of the first data retention element.

12. The integrated circuit as claimed in claim 11,
wherein the disconnection element is configured such that the second setup time is longer than the first setup time.

13. The integrated circuit as claimed in claim 11, further comprising:
a delay element, connected upstream of the data input of the second data retention element, configured to delay data supplied to a data input of the second data retention element in comparison with data supplied to the first data retention element.

14. The integrated circuit as claimed in claim 13,
wherein the delay element is configured such that its delay characteristic can be varied.

15. The integrated circuit as claimed in claim 13,
wherein the delay element has an inverter.

16. The integrated circuit as claimed in claim 15,
wherein the delay element has at least two inverters connected in series.

17. The integrated circuit as claimed in claim 16,
wherein the delay element has a variable capacitance connected between the at least two series-connected inverters.

18. The integrated circuit as claimed in claim 16,
wherein the delay element has a transmission gate connected between the at least two series-connected inverters.

19. A method for operating an integrated circuit, comprising:
supplying data to a first data retention element that retains the data, the first data retention element having a first setup time,
supplying the data to a second data retention element that retains the data, the second data retention element having a second setup time,
configuring the second data retention element, via a data input of the second data retention element, to cause the second setup time to be longer than the first setup time,
wherein the second data retention element is connected in parallel with first data retention element.

20. The method as claimed in claim 19,
wherein the first data retention element and the second data retention element are supplied with a same clock signal.

21. The method as claimed in claim 19,
wherein the first data retention element and the second data retention element are each a data retention element selected from the following set of data retention elements:
a nonvolatile memory element,
a state-controlled flipflop, and
a clock-edge-controlled flip-flop.

22. The method as claimed in claim 19, further comprising:
comparing a output signal from the first data retention element with an output signal from the second data retention element, and
generating a comparison result signal based on the comparison.

23. The method as claimed in claim 22, further comprising:
controlling the integrated data processing circuit using at least one of the following operating parameters:
an operating voltage at which at least a portion of the integrated data processing circuit is operated,
an operating frequency at which at least a portion of the integrated data processing circuit is operated,
a body voltage applied to a body of the integrated data processing circuit, and
a temperature at which at least a portion of the integrated data processing circuit is operated.

24. The method as claimed in claim 22,
controlling the integrated data processing circuit based on the comparison result signal.

25. The method as claimed in claim 19,
disconnecting the second data retention element during a test mode of the integrated data processing circuit, and
disconnecting the second data retention element during a normal mode of the integrated data processing circuit.
